(19) United States
(12) Patent Application Publication
(10) Pub. No.: US 2012/0227788 A1
(43) Pub. Date: Sep. 13, 2012

(54) Low cost sun tracking pole mount for solar panels

(75) Inventors: Robert D. Lundahl, Frederick, MD (US); Robert Wesley Cutlip, Millersville, MD (US); William Finch, New Windsor, MD (US)

(73) Assignee: Advanced Technology & Research Corp. (ATR), Columbia, MD (US)

(21) Appl. No.: 13/064,198

(22) Filed: Mar. 9, 2011

(51) Int. Cl. H01L 31/052

(52) U.S. Cl. 136/246

(57) ABSTRACT

This invention presents a robust and low cost design for a sun tracking, solar panel mounting system that can be mounted on a wide range of light poles and power poles. This design incorporates a structural base that is attached to the pole with separate “U” bolts and custom cradles that precisely accommodate the mounting pole dimensions. The structural base incorporates an axle and separate pivoting frame to hold the solar panel and allow it to rotate about the axle in a celestial tracking configuration known as an equatorial mount. A simple automotive style electric motor in the support arm interfaces with a curved gear rack of the pivoting frame to power the motion of the solar panel and frame. A control system coordinates the movement of the frame to achieve the sun tracking.

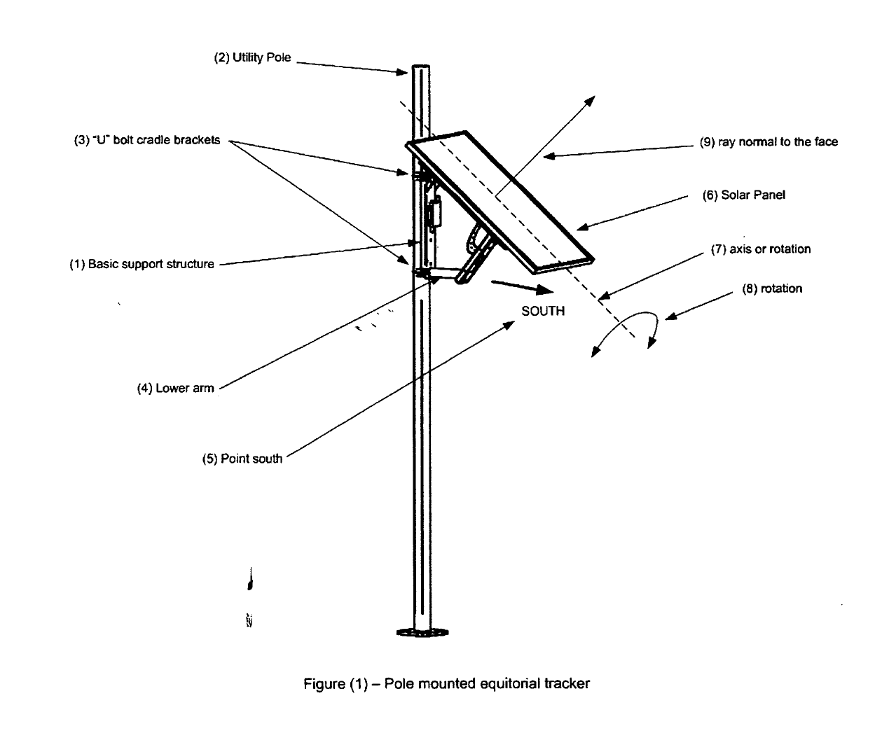

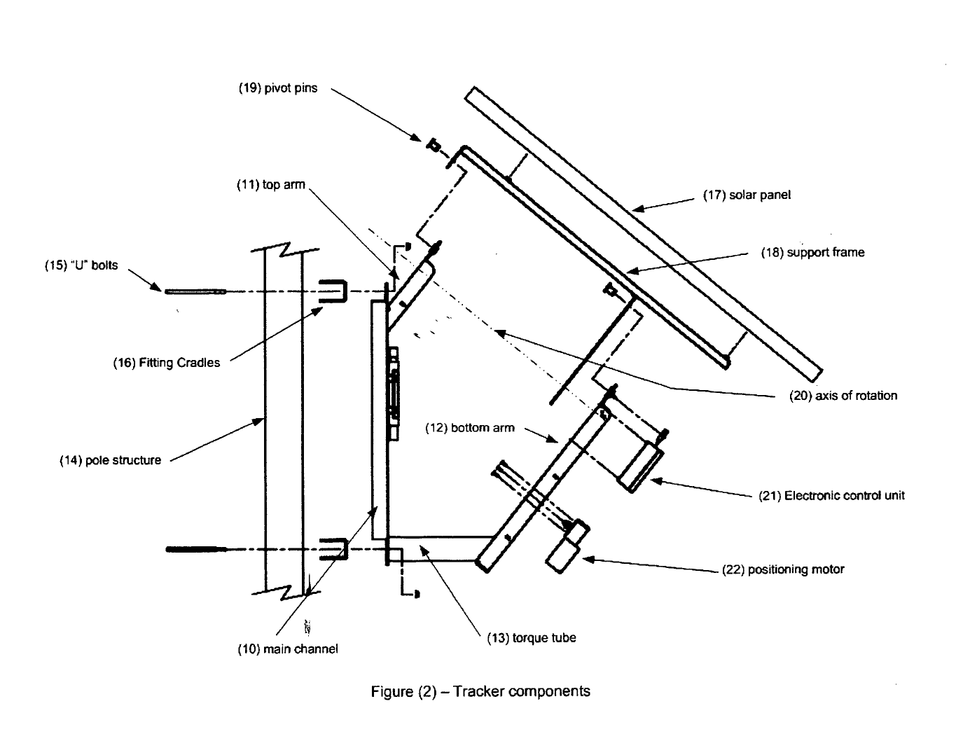

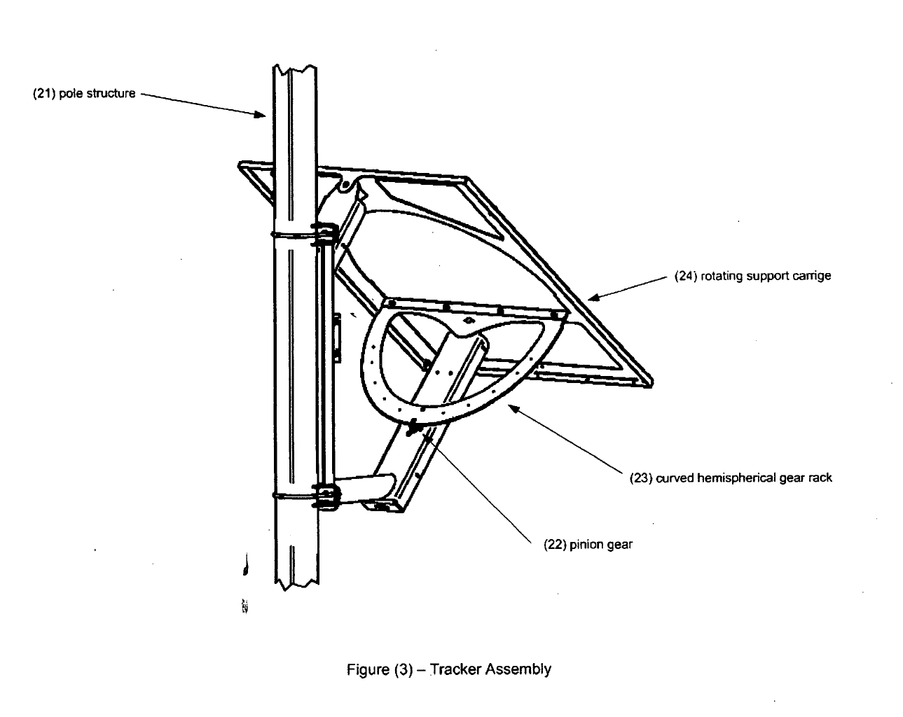

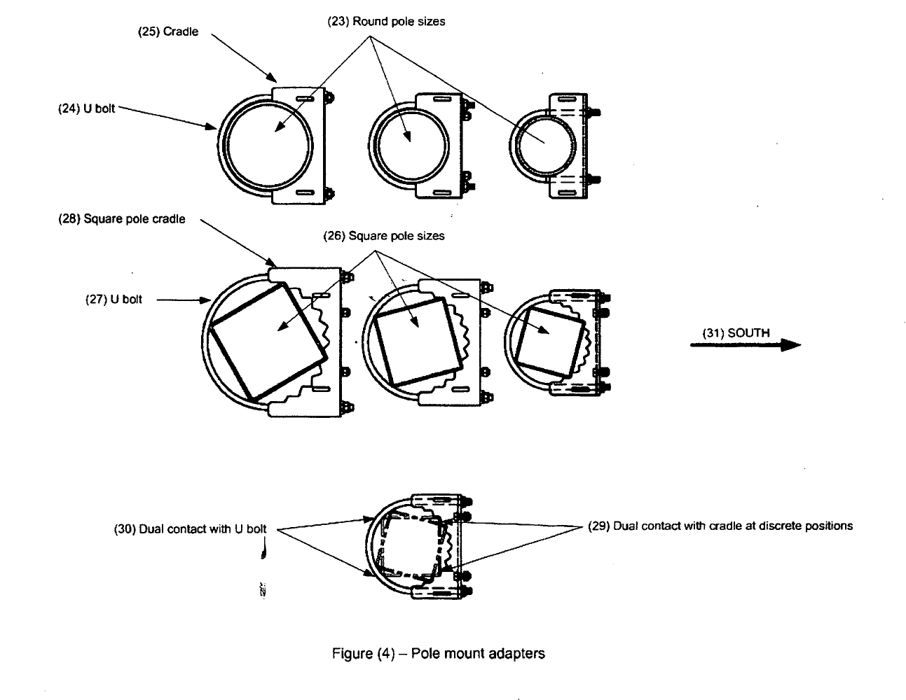

### BACKGROUND OF THE INVENTION

1. Field of the Invention

This invention relates to solar energy electrical power collection systems and specifically to the design of a low cost, sun tracking mount, designed specifically for utility power poles, light poles, and other pole supported structures.

Utility poles for lighting, power, and communications are prevalent in today's landscape. They are existing industrial structures that can be utilized to support light weight appendages and most are also connected to the local electrical power grid. These are attractive features for the location of solar panels and solar power collection systems. Using existing light poles for a mounting structure greatly reduces the cost to install the solar panels and no additional real estate is required. Utilizing existing utility poles also provides an easy access to the electrical grid so that power produced by the solar panels does not need to be stored but can be “sold” back to the grid for others to use.

Most of the current installations of solar panels on utility poles use simple fixed mounting structures where the solar panel is supported at a fixed angle and the supporting frame is permanently oriented to hold the panel in a due South facing position. These mounting systems are simple and robust. However, much of the power generation capability is lost using a fixed position without sun tracking. The power generation of a fixed panel falls off rapidly as the sun position deviates from the due south, noon time position.

This invention presents a detailed approach for the design of a low cost solar panel mounting system that incorporates an axle and pivoting solar panel for an equatorial or polar mount type sun tracking system. The power generation using equatorial sun tracking provides nearly 30% more energy and better utilizes the available pole installation site.

This tracking mount is also designed to mount easily on a wide variety of existing poles. Many of the current installations use simple structural components that are bolted together on site and attached to the poles with a variety of clamps and supports. This invention provides a standardized approach for mounting where the structure is always the same and only a simple bracket is changed to accommodate a wide range of pole sizes in both round and square configurations.

The principal application for this design is to optimize the power generation of solar cells mounted on a utility pole with a sun tracking mounting system. However, it should be obvious to one skilled in the art that this tracking mount system could be used on any pole type structure as well as utilized for a variety of other tracking or pointing applications of other antennas, cameras, etc.

### BRIEF DESCRIPTION OF PRIOR ART

Prior art shows several different static mounting configurations for solar panels where the emphasis has been on low cost and flexibility in the physical interface with the pole itself.

U.S. Pat. No. 4,265,433 titled “Pole Mounted Solar Panel Assembly” describes a technique where the solar panel mounting brackets are constructed from sheet metal and formed into two, 3 dimensional shapes that are attached to the poles separately with a plurality of hose clamp type fasteners. This is certainly a simple and low cost approach. However, it would require a level of final fitting in the field and the design will not support sun tracking for the solar panel. The solar panel cannot pivot and the mount brackets supporting the panel are not oriented in a manner that could support a simple rack and pinion drive mechanism. The clamping arrangement for securing the fixed brackets to the poles is also limited in their ability to accommodate different pole sizes and shapes. Different pole diameters will change the width of the mounting brackets since these bracket are flexible and wrap around the diameter of the pole itself. The clamping arrangement is similarly limited in the ability to interface with square poles and securely maintain a south pointed direction with a positive engagement with the corners of the pole.

Sun tracking is a common technique used to increase the energy yield of solar energy collection systems. The technical benefits of sun tracking versus a fixed mount are well understood. However, the cost and complexity of the tracking system is a great concern since the economic benefits of the solar panels with tracking can be directly compared to the increased value of the increased energy yield.

U.S. Pat. No. 4,368,962 titled “Solar Tracking Apparatus and System” describes an equatorial tracking system designed for solar devices. This tracking system is also aligned with the Earth's polar axis and incorporates an additional automatic adjustment for the yearly change in the Earth's axis relative to the sun. This device in not a low cost approach for sun tracking as it incorporates several rotating shafts, gears, and a gimbaled mount for the solar device itself. The entire device must be positioned parallel with the solar axis. However, there are no provisions for mounting this device, in the polar orientation, to a pole structure.

The subject of this invention is a simple mechanical approach for sun tracking where a fixed axle is correctly positioned by the mounting structure and the solar array is rotated around it at the same speed as the rotation of the earth. The design described in this invention has a low manufacturing cost, it is adaptable to a wide range of round and square pole configurations, and it is easy to install with a common approach for all pole types.

### SUMMARY OF THE INVENTION

This invention presents a unique design of a solar tracker that is a pole mounted, equatorial or “polar mount” style tracker, and it is inexpensive to build and optimized for installation on conventional light poles. The mechanical simplicity and low cost are critical to an overall concept of providing a cost effective solution for a distributed power generation system. With a simple and low cost design, many such devices can be installed on large sets of light poles and collectively provide a significant power generation resource. Simplicity, low cost, and ease of installation are key attributes of this design and critical for its intended utility.

This invention describes a single “C” shaped mounting structure designed to be clamped to the mounting pole. The structure itself is simple and designed to utilize modern low cost manufacturing techniques such as laser cut sheet metal, tube bending, and folded construction.

The mount structure is attached to the pole using a common “U” bolt style connection from the mount to encircle and capture the pole. Specialized cradles are used between the mount structure and the pole itself. In this way the same mount can have a solid and secure interface with a variety of poles by simply changing the cradle configuration. Both round and square poles and straight or tapered profiles in a variety of sizes can be accommodated. The installation procedure is simple and always the same regardless of the pole sizes. Holes for common “lag bolts” are also provided to allow the mount structure to be attached directly to an appropriate wooden wall, post, column, fencepost, or even a tree.

The “C” shaped mounting structure incorporates a simple pivot point out on the end of each one of the legs. An axle is defined by these two pivot points. The legs of the “C” shaped structure have different lengths to create an angle between the pivot point axle and vertical. The length of the two legs is chosen so that the axle is canted at the same angle as the Earth's axis on the solar equinox and the entire mount is connected to the pole structure with the lower arm pointing due south. This configuration places the axle in a position parallel to the Earth's axis and is a fundamental feature of a polar or equatorial mount system.

A second frame supports the actual solar panel and is supported by the axle of the mount structure. The support frame is also designed for cost effective manufacturing techniques and include edges and other features to stiffen the structure. A large hemispherical section of the support frame is cut out and bent down at 90 degrees. The lower curved edge of this bent down section is cut out with a gear profile that will interface with a geared motor installed in the lower arm of the “C” shaped support structure. The geometry of the lower arm intersects the pivot axle at 90 degrees so that a gear motor mounted in the lower arm can interface with the curved gear of the support frame and act as a powered pinion gear to drive the hemispherical rack of the solar panel support frame and rotate this frame around the axle.

A variety of panels can be attached to the rotating support frame. Solar PV technology continues to evolve at a rapid pace and using an interim frame to support the PV panel allows for future changes in the panel design without impacting the base configuration of the tracker mount.

### OBJECT OF THE INVENTION

The object of this invention is to provide a pole mounting system for solar panels that will track the sun with a 1 axis, equatorial style tracking mount that is low cost and easily manufactured.

A further object of this invention is to provide an equatorial style tracking mount for solar panels that can be easily mounted to a wide variety of utility pole configurations without modification.

A further object of this invention is to provide an equatorial style tracking mount for solar panels that can be securely installed in the mid section of a utility pole and be pointed due south.

### BRIEF DESCRIPTION OF DRAWINGS

FIG. (1) Pole mounted Equatorial Tracker—This illustration shows the overall configuration of the pole mounted equatorial tracker and shows the orientation of the mount and the axis of motion.

FIG. (2) Tracker construction and components—This illustration show the major structural elements of the tracker and identifies the key components.

FIG. (3) Tracker components assembled—This illustration show the tracker components assembled and the drive interface with the gear rack of the panel carnage frame.

FIG. (4) Mounting cradle adapters to accommodate different pole types—This illustration shows the different mounting cradles that allow the tracker to be installed on a wide variety of pole types and diameters and still accommodate the correct due south orientation of the fixed mounting structure of the tracker.

### DETAILED DESCRIPTION OF THE INVENTION

The following sections describe only one embodiment of this invention where the application is for a solar panel tracking system. It should be obvious that this invention could be utilized for a variety of other point applications that required an equatorial path for aiming.

FIG. (1) shows the pole mounted equatorial tracker and how it is installed on a representative pole. The basic support structure (1) is attached to the utility pole (2) using one or more “U” bolt cradle brackets (3). The support structure (1) is attached to the utility pole (2) so that the torque tube (4) of the lower arm is pointed due south (5). The Solar panel (6) is mounted on a support frame (not shown) that has an axis of rotation (7). The inclination of this axis of rotation (7) and the south facing orientation of the support structure (1) will result in the axis being parallel to the axis of rotation of the earth. This is the common mechanical definition of an equatorial or polar mount tracking device. When the solar panel (6) and support frame (not shown) are rotated (8) around the axis of rotation (7), a ray (9) normal to the face of the solar panel (6) will trace a path across the sky in close approximation to the apparent path of the sun.

FIG. (2) shows the major structural elements of the tracker and how these components are assembled to form the cost effective solar panel tracking system. The basic mount structure is a welded assembly of three components. The main channel (10) is the central structure that supports the top arm (11) and the bottom arm (12) connected with the torque tube (13). The main channel is connected to the pole structure (14) with the U bolts (15) and fitting cradles (16). The solar panel (17) is attached to the support frame (18) which is in turn connected to the top arm (11) and bottom arm (12) with pivot pins (19). This construction allows the rotation of the support frame (18) and the solar panel (17) about an axis of rotation (20) defined by position of the two pivot pins (19). The bottom arm (12) also provides a convenient mounting position of the electronics control unit (21) and the positioning motor (22) that drives the rotation of the support frame (18) and solar panel (17). The bottom arm (12) is perpendicular to the axis of rotation (20) to facilitate the drive interface with the positioning motor (22).

FIG. (3) shows the assembled tracker mounted on a pole structure (21) and shows how the pinion gear (22) of the drive motor will interface with the curved hemispherical gear rack (23) of the rotating support carriage (24) that holds the solar panel.

FIG. (4) shows how different “U” bolts and mounting cradles are used to accommodate the range of different poles that are encountered in practice. Different round pole sizes (23) are accommodated with different sets of “U” Bolts (24) and matching cradles (25). Different square pole sizes (26) are similarly accommodated with other “U” bolt (27) and square cradle (28) combinations. The design of these cradle for the square poles allows the different square pole (26) to have 2 contact points in the cradle (29) and 2 contact points with the U bolts (30) for a secure mounting method at various angles. The ability to mount the tracking device at these interim angles is an important feature to allow the correct South (31) facing mounting position regardless of the orientation of the support pole.

What is claimed:

1) A solar power generation system where one or more solar panels is attached to a utility pole with a mounting bracket and
said mounting bracket provides the means to support a pivoting member in approximate alignment with the earths axis and,
said pivoting member supports said solar panels and,
said pivoting member is driven by an electric motor and control system to rotate said solar panel(s) in coordination with the path of the sun during the course of the day to maximize the daily power generation.

2) A solar power generation system in accordance with claim 1 whereas the power generated by the solar panel is converted to grid tied alternating current and provide back to the utility wiring in the base of the utility pole for the purpose of gaining credit for the power generated.

3) A solar power generation system in accordance with claim 1 whereas the power generated by the solar panel is used directly to power Direct Current Devices or charge battery banks.

4) A solar power generation system in accordance with claim 1 whereas the mounting bracket is attached to the pole using a “U” bolt and cradle configuration and different configurations of said “U” bolts and cradles can be designed to interface with different diameters and shapes of said pole with the same mechanical interface with said mounting bracket.

5) A solar power generation system in accordance with claim 1 whereas the mounting bracket is attached to the pole using a thru-bolt and cradle configuration and different configurations of said thru-bolt and cradles can be designed to interface with different diameters and shapes of said pole with the same mechanical interface with said mounting bracket.
